(19) United States
(12) Patent Application Publication
(10) Pub. No.: US 2003/0132802 A1
(43) Pub. Date: Jul. 17, 2003

(54) Adaptive controller

(76) Inventors: Steven Richard Ring, Yate (GB); Kevin Neil Browne, Axbridge, Somerset (GB)

Correspondence Address: JOHN S. PRATT, ESQ, KILPATRICK STOCKTON, LLP, 1100 PEACHTREE STREET, SUITE 2800, ATLANTA, GA, 30309, US

(21) Appl. No.: 10/182,988

(22) PCT Filed: Jan. 29, 2001
(86) PCT No.: PCT/GB01/00355

(30) Foreign Application Priority Data
Jan. 30, 2000 (EP) 0002199.8

(51) Int. Cl. H03F 1/26

(52) U.S. Cl. 330/149

(57) ABSTRACT

The pre-distorter controller determines at (210) if the residual distortion in the amplifier output is above a threshold. If so, the phase and amplitude of a pre-distortion signal combined with the amplifier input signal are adjusted sequentially to reduce the residual distortion below the threshold. When the residual distortion falls below the threshold, step (214) determines if the residual distortion is below a second, smaller, threshold. If not, step (218) makes small adjustments to the phase and amplitude of the pre-distortion signal sequentially and the residual distortion is again tested at (214) to determine if it is now below the second threshold. If it is, then further adjustments are not made unless the residual distortion level moves above the second threshold. The control process can also be used with a feed forward lineariser to minimise output distortion (FIG. 5) or unwanted input signal components in the signal led forward (FIG. 6).

This application relates to methods and apparatus for controlling distortion reduction mechanisms of the kind used to reduce the distortion which a signal handling means imposes upon a subject signal.

Known distortion reduction mechanisms include pre-distorters and feed forward linearisers.

Pre-distorters operate by distorting the input signal to a signal handling means (such as an amplifier) in order to counteract distortion which the signal handling means itself imposes on the input signal.

Feed-forward linearisers operate by deriving a distortion signal which can be subtracted from the output of a signal handling means thus reducing the distortion to acceptable levels. The distortion signal is derived by finding the difference between a sample of the distorted output signal and a sample of the input signal.

A known kind of pre-distorter combines a pre-distortion signal with an input signal to the signal handling means. A control mechanism is used to adjust the pre-distortion signal to maximise the suppression of the distortion produced by the signal handling means. The process of adjusting the pre-distortion involves splitting the pre-distortion signal into in-phase (I) and quadrature (Q) components, making independent adjustments to the amplitude of the I and Q components, and recombining the I and Q components to produce the adjusted pre-distortion signal for combination with the input signal. The amplitude adjustments made to the I and Q signals effect phase and amplitude adjustment of the pre-distortion signal.

The adjustment of the I and Q components of the pre-distortion signal is made in response to an input distortion error signal containing information about the distortion present at the output of the signal handling means. This input distortion error signal has I and Q components conveying information about the phase and amplitude of the distortion error.

A problem can arise when the I and Q adjustments are each made on the basis of “corresponding” I and Q components of, for example, a feedback signal from the output of the signal handling means. If the I and Q components of the pre-distortion signal and the I and Q components of the feedback signal are not correctly aligned in signal space, then changing the amplitude scaling applied to the I component of the pre-distorter signal has an effect on the Q component of the feedback signal. Similarly, changes to the Q component of the pre-distortion signal will have an effect on the I component of the feedback signal. The pre-distorter may be calibrated to align the I and Q axes of the pre-distortion and feedback signals, but such a calibration process may be impractical or undesirable.

According to one aspect, the invention provides a method of reducing distortion appearing in the output signal produced by a signal handling means in response to an input signal by predistorting the input signal by combining the input signal with a predistortion signal, the method comprising monitoring the broadband amplitude of the error in the output signal and adjusting directly the amplitude, phase or both the phase and amplitude of the predistortion signal to minimise said monitored amplitude.

According to another aspect, the invention provides a method of reducing distortion appearing in the output signal produced by a signal handling means in response to an input signal by combining the input and output signals to produce a distortion signal and combining the distortion signal with the output signal, the method comprising monitoring the broadband amplitude of the error in the output signal and adjusting directly the amplitude, phase or both the phase and amplitude of the distortion signal to minimise said monitored amplitude.

According to a further aspect, the invention provides a method of reducing distortion appearing in the output signal produced by a signal handling means in response to an input signal by combining the input and output signals to produce a distortion signal and combining the distortion signal with the output signal, the method comprising monitoring the broadband amplitude of input signal residue in the distortion signal and adjusting directly the amplitude, phase or both the phase and amplitude of the input signal to minimise said monitored amplitude.

The invention extends to corresponding apparatus, as defined in the claims.

The invention may therefore ameliorate at least some of the problems associated with misalignment of the signal space components of a controlled signal used in distortion reduction and the signal space components of a signal indicative of an error to be minimised (eg., a feedback signal derived from the output of the signal handling means).

In a preferred embodiment, phase and amplitude adjustments are performed incrementally, and the size of increments depends upon the size of the monitored amplitude. Convergence to the minimum error condition (i.e. where the monitored amplitude is minimised) may thus be achieved more swiftly. In this embodiment, the amplitude and phase adjustments may be performed using smaller steps when the error is below a threshold.

In a preferred embodiment, the sense of changes in the monitored amplitude in response to previous variations of at least one of amplitude and phase may be assessed to ascertain if the amplitude and phase are being adjusted in the correct sense to achieve minimisation of the monitored amplitude. For example, if clockwise phase rotation of the phase of the signal being adjusted leads to an increase in the magnitude of the monitored amplitude, then future adjustments to the phase are made in the anti-clockwise direction. This may facilitate the location of the minimum of the monitored amplitude. Also, the sense of changes in the monitored amplitudedue to systematic or environmental changes may advantageously be observed to guide future changes to control variables.

In a preferred embodiment, the signal being adjusted is a vector signal. Independent adjustments of amplitude and/or phase may be made by providing appropriate signals to a vector modulator operating on that signal. For example, an amplitude adjustment may be effected by providing the same change to the I and Q inputs of the vector modulator.

In another embodiment, the signal being adjusted is not in vector format (ie., not comprised of I and Q components) and that signal is treated as indicative of the magnitude of the error.

Preferably, the signal handling means is signal amplifying means, such as a RF power amplifier.

By way of example only, certain embodiments of the invention will now be described with reference to accompanying figures, in which:

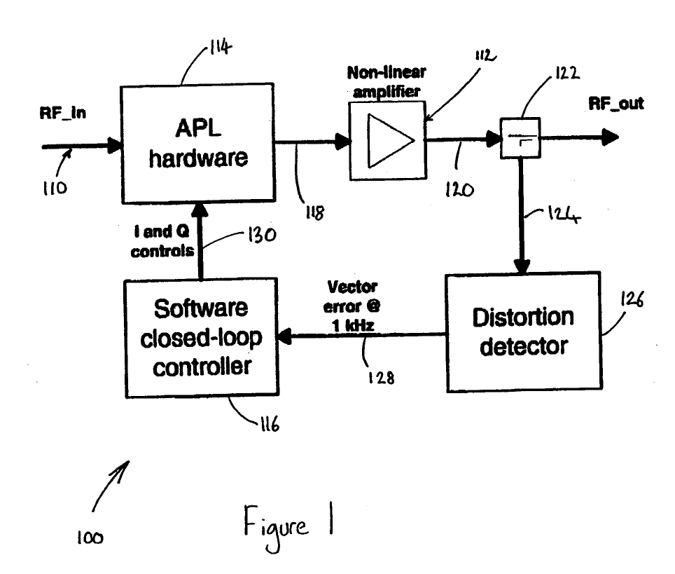

FIG. 1 is a schematic diagram of an adaptive pre-distorter;

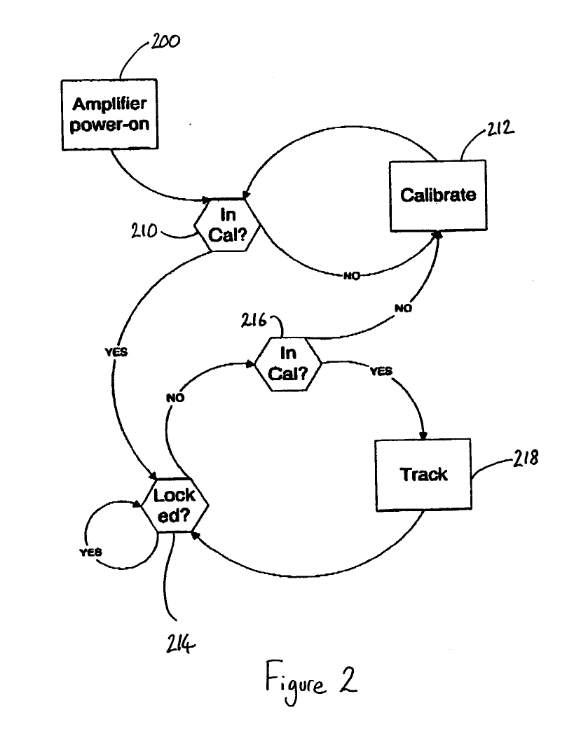

FIG. 2 is a flow chart of a control process performed by the pre-distorter;

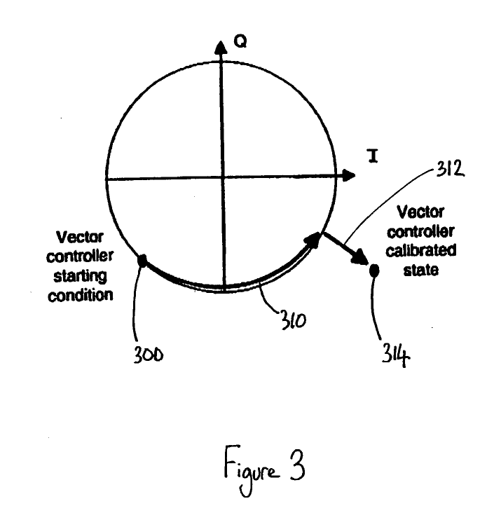

FIG. 3 is a signal space diagram illustrating the calibration process;

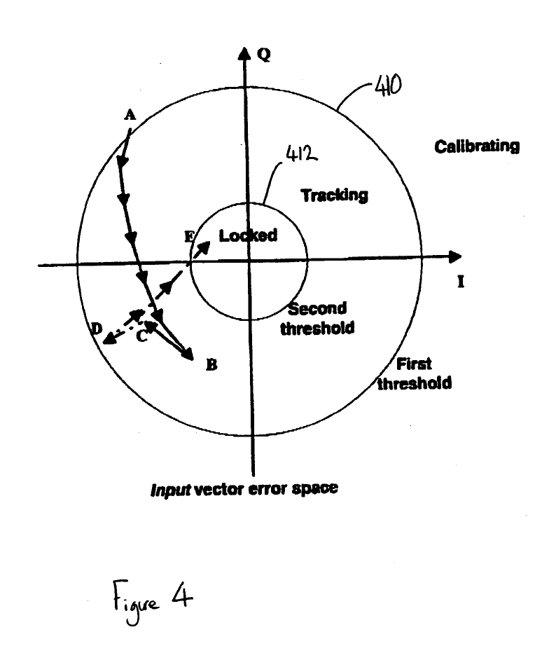

FIG. 4 is a signal space diagram illustrating the tracking process;

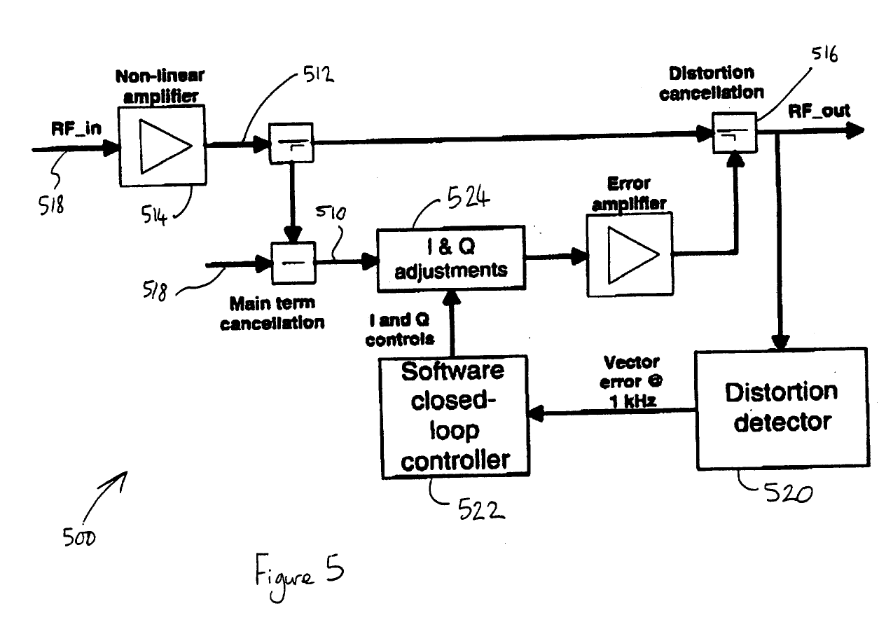

FIG. 5 is a schematic diagram of a feed-forward lineariser showing the feed forward distortion cancellation loop; and

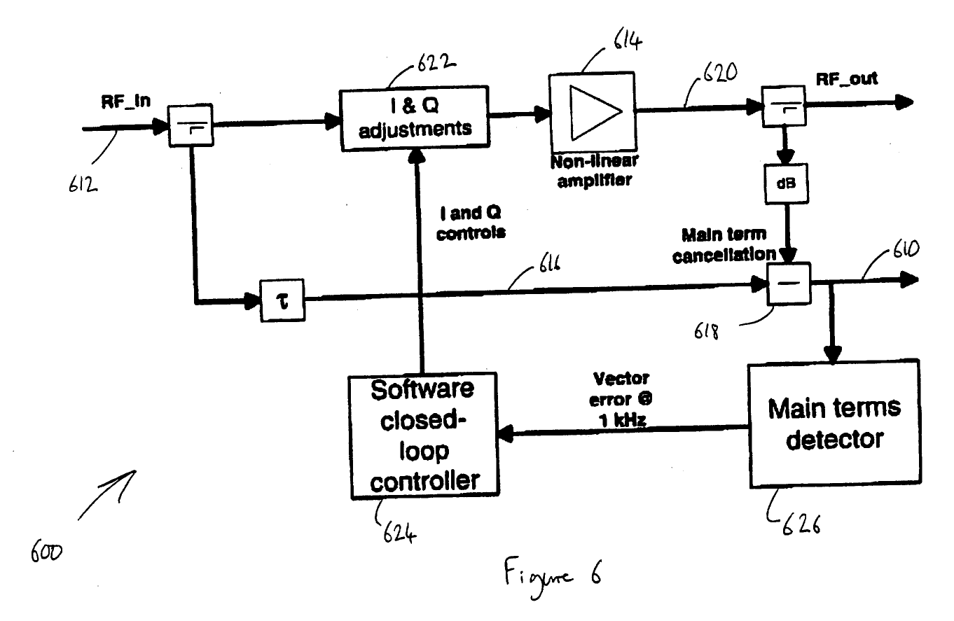

FIG. 6 is a schematic diagram of a feed-forward lineariser showing the main term cancellation loop.

FIG. 1 shows a pre-distorter 100 which pre-distorts the input signal 110 to non-linear power amplifier 112. The pre-distorter 100 contains APL (adaptive parametric lineariser) hardware 114 which pre-distorts the input signal 110 under the control of software closed-loop controller 116. The pre-distorter hardware 114 samples the input signal 110 and creates odd-order versions of the input signal (such as 3rd, 5th and 7th order equivalents) which are individually adjusted, and combined into a pre-distortion signal which is combined with input signal to produce a pre-distorted input signal 118.

The linearised output 120 of amplifier 112 is sampled at 122. The sample 124 of the output signal is supplied to distortion detector 126. The distortion detector 126 determines whether the sample 124 (and hence output signal 120) contains residual distortion due to amplifier 112 which has not been cancelled by the pre-distorter hardware 114. The distortion detector 126 provides a vector error signal 128, indicative of any residual distortion, to controller 116. The vector error signal is in quadrature format and contains I and Q components.

The controller 116 uses the vector error signal to produce control signals 130 for adjusting the pre-distortion produced by pre-distorter hardware 114. The control signals 130 comprise a pair of I and Q control signals which is used by an I and Q vector modulator operating on I and Q components of the pre-distortion signal.

The controller 116 converts the quadrature components (I_{de}, Q_{de}) of the vector error signal into amplitude (A_{de}) and phase (P_{de}) using the following equations:

A_{de}=SQRT[I_{de}²+Q_{de}²] Equation 1.

P_{de}=ARCTAN[I_{de}/Q_{de}] Equation 2.

After the distortion error input has been processed by the controller 116, the controller 116 produces amplitude and phase pre-distortion control signals (A_{pc} and P_{pc}), which can then be used to adjust the pre-distortion to be applied to the input of the amplifier 112 to minimise the distortion error. The controller 116 converts the amplitude and phase outputs (A_{pc}, P_{pc}) back into quadrature format (I_{pc}, Q_{pc}) using equations 3 and 4:

I_{pc}=A_{pc}*COS[P_{pc}] Equation 3.

Q_{pc}=A_{pc}*SIN[P_{pc}] Equation 4.

The generation of the I and Q control signals 130 will now be described with reference to FIGS. 2 and 3.

The flow chart of FIG. 2 illustrates the control processes which are performed in controller 116. At 200, the amplifier is switched on. The process then moves to step 210, where it is determined if the pre-distorter is “calibrated”. It is determined that the pre-distorter is calibrated if the vector error 128 is below a first threshold. If the vector error 128 is not below the threshold then the process moves to calibration step 212.

The following procedures are performed by calibration step 212. The phase control of the pre-distortion signal is rotated through 360° to locate the minimum in the vector error signal. For example, FIG. 3 illustrates the signal space settings for the I and Q control signals 130 output by controller 116 for the vector controller. The starting values (I and Q) of the vector controller relating to the pre-distortion are given by starting point 300. The phase of the vector controller is rotated anti-clockwise and the vector controller state rotates counter-clockwise in signal space along arrow 310, maintaining a constant radius from the signal space origin. Whilst this phase rotation is taking place, the distortion vector error 128 is monitored by the controller 116 until the minimum error amplitude is detected. At this point, the phase element of the vector controller output is said to be calibrated.

The calibration step 212 then operates on the amplitude of the vector controller signal. This is achieved by adjusting the amplitude using the vector controller and noting if the vector error increases or decreases. If the vector error decreases then the calibration step continues to adjust the vector controller amplitude in the same direction until the vector error reduces to a minimum and increases again. The amplitude of the vector controller can be said to be calibrated when the vector error signal 128 supplied to controller 116 has been minimised in terms of both phase and amplitude. In this example, the amplitude adjustment applied to the vector controller is illustrated by arrow 312 in FIG. 3, which corresponds to an increase in radius. The vector controller I and Q control inputs then specify point 314 in signal space, which corresponds to the calibrated state of the vector controller (meaning that the vector error has been minimised).

The controller 116 is responsible for sending the correct I and Q control signals 130 to the pre-distorter to effect the phase rotation (310 in FIG. 3) and amplitude adjustment (312 in FIG. 3) to minimise the vector error signal 128. The I and Q components of the vector error signal 128 are effectively decoupled from the I and Q control signals supplied to the pre-distorter hardware 114. In prior art systems, the I and Q components of the vector error signal 128 are each used directly and independently to produce the corresponding I and Q control signals 130. In contrast, in the present system, the software controller 116 externally adjusts the I and Q control signals 130 of the vector modulator in the pre-distorter hardware 114 as determined by Equations 3 and 4 and the amplitude and phase control signals (A_{pc}, P_{pc}) used inside the controller 116 to find a minimum point in the amplitude of the vector error 128.

Returning to FIG. 2, when the vector error 128 is minimised, the pre-distorter is said to be calibrated and the process moves from step 210 to lock step 214. The lock step 214 tests whether or not the vector error signal 128 is less than a second threshold, called the lock range (which is smaller than the first threshold used in the calibration step). If the vector error signal is less than the lock range, the process is suspended and the lock step is periodically repeated until the vector error signal becomes greater than the lock range. Should the vector error signal become greater than the lock range, the process moves to step 216 which determines whether or not the vector error signal is less than the first threshold. If it is not, then the process moves to calibration step 212, which performs the procedures as previously described. If step 216 determines that the vector error signal is less than the first threshold, then processing moves to tracking step 218.

The tracking step 218 performs small regular adjustments to the I and Q control signals 130 to adjust both the phase and magnitude of the control effected by the vector controller. In the tracking step, the phase and amplitude of the pre-distortion is adjusted independently and sequentially as shown in FIG. 4.

With reference to FIG. 4, after the calibration process has been achieved by crossing the first threshold 410 at A, the controller 116 initiates the tracking step 218. First the control signals 130 are adjusted to change the amplitude of the pre-distortion signal. The effect of these sequential amplitude changes on the vector error 128 are illustrated by solid arrows in FIG. 4. It should be noted that the error vector at a particular instant is from the signal space origin to the tip of the arrow representing the effect of the last change to the control signals 130. In other words, the arrows in FIG. 4 each represent a vector change in the vector error 128, caused by a corresponding change to the control signals 130.

Progressing from point A, it will be seen that the magnitude of the vector error 128 reduces after the first amplitude change effected by control signals 130, so further amplitude changes in the same sense and further vector error magnitude checks are made until the vector error reaches point C. It is then found that the next amplitude change in the same sense to point B causes an increase in the vector error magnitude. The controller 116 reverses this last amplitude change to bring the vector error 128 back to point C.

The tracking algorithm 218 then attempts to reduce the vector error magnitude by adjusting the control signals 130 to effect an adjustment of the phase of the pre-distortion signal. The effects of phase adjustments on the vector error 128 are shown by broken arrows in FIG. 4. The first phase adjustment causes an increase in the vector error magnitude to point D. The controller 116 detects this and reverses the phase adjustment to return the vector error 128 to point C. Then further phase adjustments are made to reduce the vector error magnitude. At point E, the controller 116 detects that the magnitude of the vector error 128 has crossed the second threshold 412 and therefore ceases to adjust the control signals 130 as the locked condition has been achieved.

As a refinement of the basic technique, the first and second thresholds 410, 412 described can each be implemented as a pair of proximate thresholds. Each proximate pair of thresholds consists of an exit and entry threshold. Each proximate pair of thresholds can then allow hysteresis to be implemented around the boundaries between the ‘calibrating’, ‘tracking’ and ‘locked’ regions in the control mechanism. For example, where the process moves from step 210 to 214 the transition at the second threshold 412 is based on the vector error signal 128 being less than the lower of the proximate pair of second thresholds (considered to be an entry threshold), referred in the text as track range. Exiting the track range, for example, where the process moves from step 216 to step 212 the transition is based on the vector error signal 128 being greater than the upper of the pair of proximate second thresholds (considered to be an exit threshold). As a further refinement of the basic technique or the technique including hysteresis, transitions shall only be valid when the threshold crossing is sustained for a predetermined period. This de-bounce feature allows the controller to avoid unnecessary responses to input transients which might otherwise confuse its operation.

It will be apparent that many other modifications can be made to the embodiment described above. For example, the balance between the speed of convergence in the tracking mode and the size of the minimum error magnitude can be tailored by choosing the most appropriate step sizes for magnitude and phase changes used for the calibration and tracking steps.

The tracking algorithm may be refined by adapting the amplitude and phase step sizes used in the tracking step in dependence upon the vector error size. For example, the phase and amplitude adjustment step sizes could be related to the size of the vector error signal compared to the first and second thresholds. Hence, if the vector error is large, then larger, less accurate, steps of amplitude and phase can be used to move the signal space state of the I and Q signals applied to the vector controller quickly into roughly the right signal space region (ie., near the calibrated state 314). When the input error magnitude reduces, then smaller, more accurate, steps can be used to improve the precision. There can be a graded scale of step sizes to achieve the best balance of convergence speed and accuracy.

A further refinement is to derive the phase and amplitude information from the vector error signal to ensure that the control signals 130 are adjusted in the correct phase and amplitude directions to minimise the vector error 128 during the calibration and/or tracking modes. By detecting the sense of changes in the phase and amplitude of the vector error signal, the phase control changes implemented by the vector controller during the tracking step will always be made in the correct direction. This refinement improves the convergence or re-convergence speed of the controller 116, since otherwise, time is wasted adjusting the controller outputs 130 in the wrong direction.

The control processes implemented by controller 116 are also applicable to feed forward linearisers, as will now be described with reference to FIGS. 5 and 6.

In the feed forward lineariser 500 of FIG. 5, an error signal 510, derived from the output 512 of the amplifier 514 under linearisation is fed forward to be recombined with the output 512 further downstream at 516 to cancel distortion appearing in the output 512. The error signal 510 is derived by sampling the output 512 and subtracting from it the input signal 518 to amplifier 514 to leave just signal components due to distortion in the output 512. The creation of the error signal 510 will be discussed with reference to FIG. 6 later.

In FIG. 5, the linearised output of amplifier 514 is sampled by distortion detector 520, which provides a vector error signal to controller 522, which, in turn, develops control signals from the vector error signal for application to vector controller 524. The operation of detector 520, controller 522 and vector controller 524 is analogous to the operation of detector 126, controller 116 and the vector controller in pre-distorter hardware 114 of pre-distorter 100 of FIG. 1. The controller 522 operates to minimise the residual distortion detected in the output signal by detector 520 using the earlier-described calibration and tracking techniques.

FIG. 6 illustrates a feed forward lineariser 600 and, in particular, the creation therein of the error signal 610, which corresponds to error signal 510 in FIG. 5. The input signal 612 to the amplifier 614 undergoing linearisation is sampled and the sample 616 is supplied to subtractor 618. The subtractor is also supplied with the non-linearised output 620 of amplifier 614. The subtractor 618 subtracts the sample 616 from the output to produce the error signal 610, which should contain only components corresponding to the distortion caused by the amplifier. However, it is possible that the error signal may contain unwanted ‘main terms’ or, in other words, unwanted input signal components which will be detrimental to the distortion reduction achieved by combining the error signal 610 with the output 620 at a downstream point not shown (but illustrated in FIG. 5).

To eliminate these unwanted input signal components a vector controller 622 makes appropriate adjustments to the input signal 612 so that input signal components cancel at subtractor 618. The adjustments applied by vector controller 622 are determined by controller 624 on the basis of residual input signal components being detected in the error signal 610 by detector 626. The operation of vector controller 622, controller 624 and detector 626 is analogous to the operation of the vector controller in pre-distorter hardware 114, controller 116 and detector 126 in FIG. 1, except that in lineariser 600, it is unwanted input signal components in the error signal and not residual distortion in the linearised output of the amplifier which is subjected to the calibration and tracking operations. It should be noted that the vector controller could be located to operate on the input signal sample 616 instead.

1. A method of reducing distortion appearing in the output signal produced by a signal handling means in response to an input signal by predistorting the input signal by combining the input signal with a predistortion signal, the method comprising monitoring the broadband amplitude of the error in the output signal and adjusting directly the amplitude, phase or both the phase and amplitude of the predistortion signal to minimise said monitored amplitude.

2. A method of reducing distortion appearing in the output signal produced by a signal handling means in response to an input signal by combining the input and output signals to produce a distortion signal and combining the distortion signal with the output signal, the method comprising monitoring the broadband amplitude of the error in the output signal and adjusting directly the amplitude, phase or both the phase and amplitude of the distortion signal to minimise said monitored amplitude.

3. A method of reducing distortion appearing in the output signal produced by a signal handling means in response to an input signal by combining the input and output signals to produce a distortion signal and combining the distortion signal with the output signal, the method comprising monitoring the broadband amplitude of input signal residue in the distortion signal and adjusting directly the amplitude, phase or both the phase and amplitude of the input signal to minimise said monitored amplitude.

4. A method according to any preceding claim, wherein the adjusting step comprises adjusting only one of the phase and amplitude of the adjusted signal at a time by varying vector components of the adjusted signal.

5. A method according to any preceding claim wherein the adjusting step operates incrementally and the size of the increments depends upon the size of the monitored amplitude.

6. A method according to claim 5, wherein the adjusting step operates incrementally to reduce the monitored amplitude below a low threshold which is lower than a high threshold, the size of the increments used when the monitored amplitude is above the high threshold being greater than the size of the increments used when the monitored amplitude is below the high threshold.

7. A method according to claim 5, wherein the size of the increments is proportional to the size of the monitored amplitude.

8. A method according to claim 6 wherein the high threshold is selected from a plurality of thresholds depending on the sense of the change in the monitored amplitude.

9. A method according to claim 6 or 8, wherein the low threshold is selected from a plurality of thresholds depending on the sense of the monitored amplitude.

10. A method according to any one of claims 6, 8 or 9, wherein the monitored amplitude is deemed to have crossed a particular threshold only after it has traversed that threshold for a given time.

11. A method according to any preceding claim, wherein the adjusting step comprises examining the sense of changes in the monitored amplitude to ascertain the required sense of adjustments to be applied to reduce the monitored amplitude towards the minimum.

12. A method according to claim 11, wherein the amplitude changes examined are in response to changes made to at least one of amplitude and phase of the adjusted signal.

13. A method according to claim 11 or 12, wherein the amplitude changes examined are in response systematic or environmental changes.

14. A method according to any preceding claim comprising adjusting both phase and amplitude of the adjusted signal to minimise the monitored amplitude.

15. A method according to any preceding claim wherein the signal handling means is signal amplifying means.

16. Apparatus for reducing distortion appearing in the output signal produced by a signal handling means in response to an input signal by predistorting the input signal by combining the input signal with a predistortion signal, the apparatus comprising means for monitoring the broadband amplitude of the error in the output signal and means for adjusting directly the amplitude, phase or both the phase and amplitude of the predistortion signal to minimise said monitored amplitude.

17. Apparatus for reducing distortion appearing in the output signal produced by a signal handling means in response to an input signal by combining the input and output signals to produce a distortion signal and combining the distortion signal with the output signal, the apparatus comprising means for monitoring the broadband amplitude of the error in the output signal and means for adjusting directly the amplitude, phase or both the phase and amplitude of the distortion signal to minimise said monitored amplitude.

18. Apparatus for reducing distortion appearing in the output signal produced by a signal handling means in response to an input signal by combining the input and output signals to produce a distortion signal and combining the distortion signal with the output signal, the apparatus comprising means for monitoring the broadband amplitude of input signal residue in the distortion signal and means for adjusting directly the amplitude, phase or both the phase and amplitude of the input signal to minimise said monitored amplitude.

19. Apparatus according to any one of claims 16 to 18, wherein the the adjusting means is arranged to vary only one of the amplitude and phase of the adjusted signal at a time by varying the vector components of the adjusted signal.

20. Apparatus according to any one of claims 16 to 19, wherein the adjusting means is arranged to vary the adjusted signal incrementally and the size of the increments depends upon the size of the monitored amplitude.

21. Apparatus according to claim 20, wherein the adjusting means is arranged to vary the adjusted signalincrementally to reduce the monitored amplitude below a low threshold which is lower than a high threshold, the size of the increments used when the level is above the high threshold being greater than the size of the increments used when the monitored amplitude is below the high threshold.

22. Apparatus according to claim 20, wherein the size of the increments is proportional to the size of the monitored amplitude.

23. Apparatus according to claim 21, wherein the high threshold is selected from a plurality of thresholds depending on the sense of the change in the monitored amplitude.

24. Apparatus according to claim 21 or 23, wherein the low threshold is selected from a plurality of thresholds depending on the sense of the monitored amplitude.

25. Apparatus according to any one of claims 21, 23 or 24, wherein the monitored amplitude is deemed to have crossed a particular threshold only after it has traversed the threshold for a given time.

26. Apparatus according to any one of claims 16 to 25, wherein the adjusting means is arranged to examine the sense of changes in the monitored amplitude to ascertain the required sense of variations to be applied to reduce monitored amplitude towards a minimum.

27. Apparatus according to claim 26, wherein the amplitude changes examined are in response to changes made to at least one of the phase and amplitude of the adjusted signal.

28. Apparatus according to claim 26 or 27, wherein the amplitude changes examined are in response to systematic or environmental changes.

29. Apparatus according to any one of claims 16 to 28, wherein the adjusting means is arranged to vary both of the amplitude and phase of the adjusted signal to minimise the error.

30. Apparatus according to any one of claims 16 to 29, wherein the signal handling means is signal amplifying means.

31. A method of reducing a distortion error substantially as hereinbefore described with reference to FIGS. 1 to 4, 5 or 6.

32. Apparatus for reducing a distortion error substantially as hereinbefore described with reference to FIGS. 1 to 4, 5 or 6.
